(19) United States
(12) Patent Application Publication
(10) Pub. No.: US 2010/0233385 A1
(43) Pub. Date: Sep. 16, 2010

(54) APPARATUS AND METHOD OF FORMING THIN LAYERS ON SUBSTRATE SURFACES

(75) Inventors: Birte Dresler, Radebeul (DE); Volkmar Hopfe, Kleingiesshuebel (DE); Ines Dani, Lichtenau (DE)

Correspondence Address: BARNES & THORNBURG LLP, 11 SOUTH MERIDIAN, INDIANAPOLIS, IN, 46204, US

(73) Assignee: Fraunhofer-Gesellschaft zur Forderung der Angewandten Forschung E.V.

(21) Appl. No.: 12/377,658

(22) PCT Filed: Aug. 29, 2007
(86) PCT No.: PCT/DE07/01579

§ 371 Date: May 5, 2010

(30) Foreign Application Priority Data
Sep. 1, 2006 (DE) 10 2006 042 328.3

(51) Int. Cl. C23C 16/48; C23C 16/00

(52) U.S. Cl. 427/578; 118/723 R; 427/569

(57) ABSTRACT

The invention relates to an apparatus and to a method of forming thin films on substrate surfaces. It is the object of the invention to provide possibilities with which thin layers can be manufactured on substrate surfaces which have a specific layer material formation with desired properties. The apparatus in accordance with the invention is made such that a feed is present for at least one gaseous precursor, which contributes to the layer formation, at a reaction chamber region above a substrate surface to be coated. A source which is a plasma source and which emits electromagnetic radiation is moreover arranged such that a photolytic activation of atoms and/or molecules of the precursor(s) takes place with the emitted electromagnetic radiation. In this respect, the plasma source should be arranged and should also be operated such that no direct influence of the plasma on the substrate surface and on the precursors resulting in the layer formation takes place.

The invention relates to an apparatus and to a method of forming thin films on substrate surfaces.

A great variety of methods are known in thin film technology to form thin films on substrate surfaces. In this respect, the formation primarily takes place under vacuum conditions, for example by CVD, PVD or PECVD techniques. It is obvious that the manufacturing effort and/or cost is substantial and only limited substrate surfaces can be coated in this manner.

Frequently, only low coating rates can be achieved or problems have to be accepted due to coating defects (e.g. droplets or an inhomogeneous film formation). Certain properties of a coating cannot be achieved, which can also apply to further methods still to be mentioned. An impairment of the film and substrate can in particular also occur on a CVD coating due to the required high temperatures.

It is also known to use electromagnetic radiation in a vacuum for CVD coatings. In this respect, electromagnetic radiation emitted from a source is directed from outside through a window into a coating chamber. Such windows must, however, be cleaned in a very complicated and/or expensive manner and transmission losses occur.

Layers can also be formed in the sol-gel technique. In this respect, not all desired layer materials can, however, be realized and very high temperatures are required for the formation and curing of the layers.

A film formation by means of plasma sources under atmospheric pressure conditions is known from DE 102 39 875 A1 and DE 10 2004 015 216 B4 and the formation of thin films from silicon nitride is known from DE 10 2004 015 217 B4. In these solutions, a plasma source is used to which a gas or gas mixture is supplied for plasma formation. The plasma gas also includes at least one component which is also used for the layer formation. However, at least one precursor gas can additionally be introduced into the plasma or into the outflowing plasma gas flow and can be utilized for the layer formation (“remote plasma activation”). However, plasma is in any case directed directly onto the substrate surface to be coated and becomes directly and actively effective for the reactive formation of layers on substrate surfaces. Light arc plasma sources or microwave plasma sources can be used as plasma sources.

It has been shown that the most varied films can be formed with these known technical solutions, as is explicitly known for silicon nitride from DE 10 2004 015 217 B4.

Specific properties and layer material compositions can, however, also not be achieved in this form.

It is therefore the object of the invention to provide possibilities with which thin layers can be manufactured on substrate surfaces which have a specific layer material formation with desired properties.

This object is solved in accordance with the invention by an apparatus having the features of claim 1. In this respect, it is also possible to work according to a method in accordance with claim 12. Advantageous embodiments and further developments of the invention can be achieved using features designated in the subordinate claims.

In this respect, the apparatus in accordance with the invention is made such that a feed is present for at least one gaseous precursor, which contributes to the layer formation, at a reaction chamber region above a substrate surface to be coated. A source which is a plasma source and which emits electromagnetic radiation is moreover arranged such that a photolytic activation of atoms and/or molecules of the precursor(s) takes place with the emitted electromagnetic radiation. In this respect, the plasma source should be arranged and should also be operated such that no direct influence of the plasma on the substrate surface and on the precursors resulting in the layer formation takes place and only the emitted electromagnetic radiation is active.

The plasma source should preferably be arranged within the reaction chamber region, with a window arranged therebetween being able to be omitted to avoid the disadvantages already mentioned in the introductory part of the description.

The invention can be used under vacuum conditions, but also at atmospheric pressure, with atmospheric pressure being understood as a pressure range from ±300 Pa around the respective ambient atmospheric pressure.

Electromagnetic radiation with wavelengths of less than 230 nm should particularly preferably be emitted by the plasma source. Electromagnetic radiation in the wavelength range of UV light and below is particularly suitable for the desired photolytic activation. This can be achieved with suitable gases for the plasma formation. The respective gas or gas mixture has an influence on the emission spectrum of the radiation and can therefore be adapted to the precursor(s) used for layer formation. The following gases can be used for the formation of the plasma alone in each case, but also as a mixture of at least two of these gases: argon, neon, helium, nitrogen, ammonia, hydrogen, oxygen, carbon dioxide, nitrogen dioxide and water vapor.

Various layers from various materials can be formed with specific stoichiometries and a specific lattice structure or network structure can be formed using the invention.

If layers should be formed using silicon, organic silicon compounds can be used as precursors.

Alternatively, or in the mixture, these can also be silanes or also halogen silanes which can also be supplied as a gas mixture and can be activated photolytically for the layer formation. The respectively desired layer material can then be formed as a thin film on the substrate surface by chemical reactions.

An amorphous silicon nitride layer containing hydrogen thus be formed as a film on silicon wafers for solar cells, for example with SiH₄ and ammonia to improve the optical properties for this application over known solutions and simultaneously to achieve a passivation effect with respect to defects.

Argon-nitrogen or an argon-ammonia mixture in a ratio of 100:1 can be used as the plasma gas for the generation of the electromagnetic radiation. The ratio of layer-forming ammonia to silane amounts to 4:1, for example. The substrate temperature during the layer formation amounts to approximately 150° C., but can be increased up to 400° C. to improve the layer properties. The deposition rate is usually in the range from 1 to 2 nm/s. The refractive index of the layers can be set within wide limits by the selection of the ratio of ammonia to silane between 1.7 and 2.3.

Saturated or non-saturated hydrocarbons, but also halocarbons, for example C₂H₂, CH₄ or C₂H₄, can be used in combination with nitrogen, ammonia or hydrogen for the layer formation with compounds containing carbon.

The invention will be explained in more detail by way of example in the following.

There are shown:

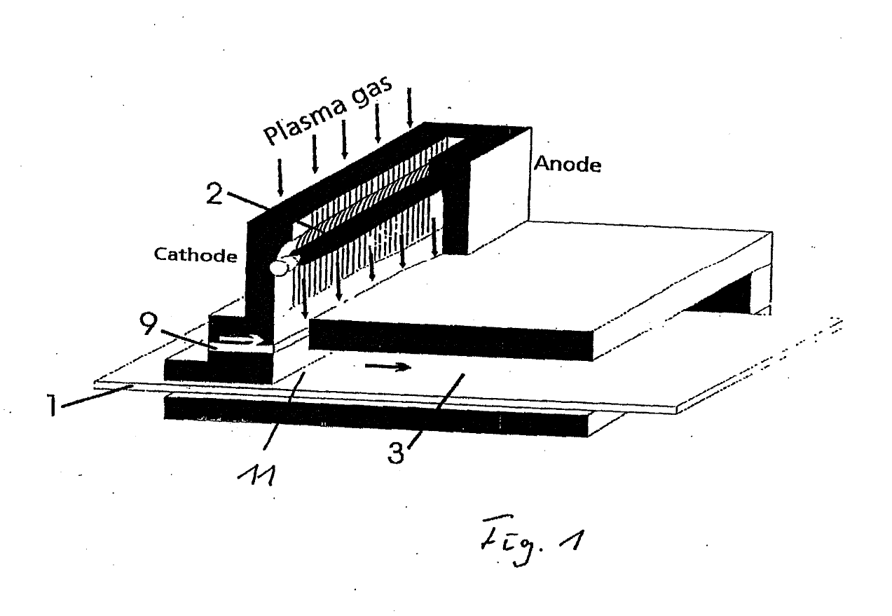

FIG. 1: a perspective representation of an example of an apparatus in accordance with the invention; and

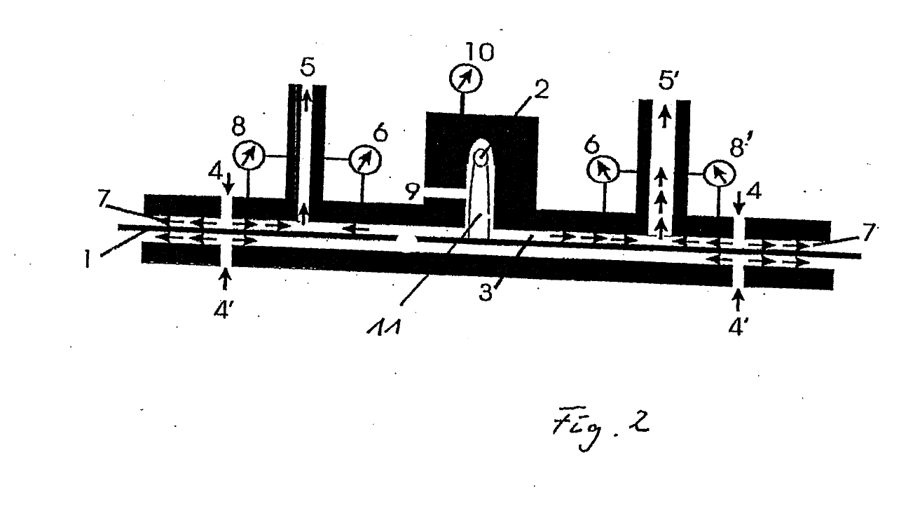

FIG. 2: a sectional representation of an apparatus in accordance with FIG. 1.

The apparatus shown for the invention and in FIGS. 1 and 2 can have at least a similar structure to that already addressed in the introduction to the description for the formation of layers at atmospheric pressure by means of plasma. Only an arrangement differing therefrom and/or a differing operation of the plasma source 2 has been selected.

A substrate 1, which is to be coated at a surface, is introduced through a gap 7 and is guided through the apparatus. In so doing, a relative movement takes place between the substrate 1 and the apparatus. The total surface, or at least a large part of the surface, can thus be coated.

A plasma is formed using a light arc formed between a cathode and an anode. The plasma source 2 is arranged in a windowless reaction chamber region 11. A plasma gas is supplied to the light arc.

In this respect, a volume flow and also a pressure for supplied plasma gas is selected which is sufficient for the plasma formation and thus for the emission of electromagnetic radiation, but prevents plasma from moving into a region of the reaction chamber region 11 in which the precursor is present for the formation of thin films.

One or also more gaseous precursor(s) are introduced into the reaction chamber region 11 via the feed 9. The activation of the atoms and/or molecules of the precursor(s) takes place exclusively photolytically by means of the electromagnetic radiation emitted by the plasma source 2. Chemical reactions of the precursor(s) take place by this activation and the thin film can be formed on the surface of the substrate 1.

It should be further illustrated by FIG. 2 how an apparatus suitable for use under atmospheric pressure can be formed.

In this respect a sensor 10 is present at the feed for plasma gas and a regulation can take place with its help by a determination of pressure and/or volume flow of the supplied plasma gas.

The correspondingly elongated light arc plasma source 2 aligned into the drawing plane is here arranged upwardly in a reaction chamber region 11 formed in slot form. Electromagnetic radiation emitted by the plasma is incident onto the surface of the substrate 1 to be coated and in so doing passes through gaseous precursor(s) which is/are introduced into the reaction chamber region 11 via the feed 9 closely above the substrate surface.

The superfluous reaction products can be discharged as waste gas via a waste gas extraction 5 and 5′. This can take place in the feed direction before and after the reaction chamber region 11, but also circumferentially.

An inert flushing gas can be supplied into a gap 7 via feeds 4 and 4′ formed circumferentially around the reaction chamber region 11 for sealing with respect to ambient. In this respect, the flushing gas flows out of the apparatus in one direction and toward the reaction chamber region 11 in an opposite direction. Flushing gas can, however, be removed again with the waste gas via the extraction 5 and 5′ so that none of the supplied flushing gas, but at least the greater part of the supplied flushing gas does not move into the reaction chamber region 11 and the layer forming process is not thereby impaired.

Further sensors 6 and 8 are present for a regulation of the flushing gas supply and for an extraction of waste gas.

In contrast to the representation, the reaction chamber region 11 can also be made such that it widens in as conically a manner as possible starting from the plasma source 11. A larger areal region can thereby be utilized since the emitted electromagnetic radiation anyway propagates in a diverging manner. At least the coating rate reduced with respect to a plasma-assisted process management can thus be compensated again.

The apparatus shown in FIGS. 1 and 2 has a further advantage with respect to other apparatus which can also be used with the invention. If desired, it can namely also be operated in conventional form temporarily. This is in particular favorable with a layer formation using at least two layers which are arranged above one another. The substrate 1 can, for example, as indicated by the arrow in FIG. 1, first be introduced through the apparatus from left to right. The formation of the layer takes place in this respect solely by photolytic activation in accordance with the invention. A movement of the substrate through the apparatus directed opposite thereto subsequently takes place. In this respect, the pressure and or the volume flow of the plasma gas is increased so that the layer formation can take place in the conventional manner.

It is naturally also possible to proceed in the reverse order. The procedure can, however, also be changed alternatingly in order, for example, to provide surface regions of the substrate 1 with different thin films.

1. An apparatus for the formation of a thin film on a substrate surface, wherein the apparatus including a reaction chamber, a feed for at least one gaseous precursor at a reaction chamber region above the respective substrate surface and at least one source for emitting electromagnetic radiation the electromagnetic radiation source arranged such that a photolytic activation of at least one of atoms and molecules of the at least one gaseous precursor takes place by emitted electromagnetic radiation for the formation of a layer, the source for emitting electromagnetic radiation comprising a plasma source.

2. An apparatus in accordance with claim 1, wherein the plasma source is arranged within the reaction chamber region.

3. An apparatus in accordance with claim 1, wherein the plasma source is arranged within the reaction chamber region and operated such that the plasma does not directly influence the at least one gaseous precursor.

4. An apparatus in accordance with claim 1 wherein atmospheric pressure is present at least within the reaction chamber region.

5. An apparatus in accordance with claim 4, wherein at least within the reaction chamber a pressure in the range ±300 Pa around the atmospheric pressure is present.

6. An apparatus in accordance with claim 1 wherein the plasma source comprises a source for emitting electromagnetic radiation with wavelengths less than 230 nm.

7. An apparatus in accordance with claim 1 wherein the substrate and the reaction chamber region with the plasma source are adapted to be moved relative to one another.

8. An apparatus in accordance with claim 1 further comprising a waste gas extraction is connected to the reaction chamber.

9. An apparatus in accordance with claim 1 further comprising a flushing gas feed connected to the reaction chamber.

10. An apparatus in accordance with claim 1 further including a seal formed with respect to ambient atmosphere by supplying flushing gas into a gap between the substrate surface and the reaction chamber region.

11. An apparatus in accordance with claim 1 wherein the plasma source is comprises at least one of a light arc plasma source and a microwave plasma source.

12. A method of forming a thin film on a substrate surface, the method comprising supplying at least one gaseous precursor into a reaction chamber region above the respective substrate surface; arranging a plasma source in the reaction chamber region and operating the plasma source such that the formation of a thin layer is achieved exclusively as a result of photolytic activation of at least one of atoms and molecules of the at least one gaseous precursor by the electromagnetic radiation emitted by the plasma source.

13. A method in accordance with claim 12, comprising carrying out the formation of the layer at atmospheric pressure.

14. A method in accordance with claim 12 comprising forming the plasma using a plasma gas with which electromagnetic radiation is emitted with wavelengths less than 230 nm.

15. A method in accordance with claim 12 comprising supplying a gaseous organic silicon compound as a precursor for the formation of layers including silicon.

16. A method in accordance with claim 15, wherein supplying a gaseous organic silicon compound comprises supplying at least one of a silane and a halogen silane ire-supplied.

17. A method in accordance with claim 12 supplying at least one gaseous precursor comprises supplying at least one gaseous precursor for the formation of layers including carbon, the gaseous precursor being selected from saturated or non-saturated hydrocarbons and halocarbons.

18. A method in accordance with claim 12 further comprising temporarily increasing the volume flow of plasma gas supplied by the plasma source for the plasma formation to form a layer having different parameters.

19. A method in accordance with claim 12 wherein supplying at least one gaseous precursor into a reaction chamber region, arranging a plasma source in the reaction chamber region and operating the plasma source together comprise selecting a gas from the group consisting of argon, nitrogen, ammonia, hydrogen, oxygen, carbon dioxide, nitrogen dioxide and water for the plasma formation.

20. A method in accordance with claim 12 further comprising extracting gaseous reaction products as waste gas.

21. A method in accordance with claim 12 further comprising supplying inert flushing gas to achieve sealing is achieved between the substrate surface, the reaction chamber region and the ambient atmosphere.
